(19) United States
(12) Patent Application Publication
(10) Pub. No.: US 2024/0223175 A1
(43) Pub. Date: Jul. 4, 2024

(54) NON-CONTACTING SWITCH CONTROL SYSTEM

(71) Applicant: DARWIN PRECISIONS CORPORATION, Hsinchu County (TW)

(72) Inventors: RAN-SHIOU YOU, Hsinchu County (TW); YA HAN KO, Hsinchu County (TW); CHIH-HUNG LIU, Hsinchu County (TW); CHIH-PING HSU, Hsinchu County (TW)

(21) Appl. No.: 18/143,086

(22) Filed: May 4, 2023

(30) Foreign Application Priority Data
Jan. 4, 2023 (TW) 112100226

(51) Int. Cl. H03K 17/00; H03K 17/0412; H03K 17/296; H03K 17/62

(52) U.S. Cl. CPC H03K 17/005; H03K 17/0412; H03K 17/296; H03K 17/6235

(57) ABSTRACT

A non-contacting switch control system includes: a switch set, configured to receive a sensing signal from a sensing target, the switch set including a first non-contacting switch and a second non-contacting switch; a storage unit, configured to store a control program; and a processing unit, connected to the switch set and the storage unit, and configured to execute the control program and control the switch set based on the sensing signal. The control program includes: in a first operating mode, determining whether the first non-contacting switch receives an identification signal, and obtaining a first determination result; and when the first determination result is true, configuring the non-contacting switch control system to enter a second operating mode and disabling the second non-contacting switch.

### FIELD OF THE INVENTION

The present disclosure relates to a non-contacting switch control system, in particular to a non-contacting switch control system with a function for conducting cleaning operations.

### BACKGROUND OF THE INVENTION

Non-contact products may avoid the germ transmission chain caused through contact, but may need to be constantly cleaned due to the easy accumulation of dust.

When existing non-contacting switches (e.g., floating touch switches) are cleaned by a cleaner, the non-contacting switches could be often mis-activated due to the conducted cleaning operations.

### SUMMARY OF THE INVENTION

In view of this, the present disclosure provides a non-contacting switch control system. The non-contacting switch control system includes: a switch set, a storage unit, and a processing unit. The switch set includes a plurality of non-contacting switches, and the plurality of non-contacting switches include one or more first non-contacting switches and one or more second non-contacting switches. The non-contacting switch control system of the present disclosure may include a first operating mode (i.e., a standby mode) and a second operating mode (i.e., a cleaning mode, which can be considered as a disabling mode), and may change the switch state according to the non-contacting switches receiving a sensing signal from a sensing target in a sensing region and transmit the sensing signal to the processing unit, and then a control program stored in the storage unit is executed by the processing unit. The sensing target may be an external device or a non-specified object. The processing unit may take one or more non-contacting switches of the plurality of non-contacting switches as the first non-contacting switch, and take one or more non-contacting switches as the second non-contacting switch. When the first non-contacting switch receives an identification signal in the first operating mode (i.e., the standby mode), the non-contacting switch control system may enter the second operating mode (i.e., the cleaning mode or disabling mode), and the processing unit may disable the second non-contacting switch in the second operating mode by, for example, sending a disabling instruction, so that a switch function of the non-contacting switch designated as the second non-contacting switch in the plurality of non-contacting switches is disabled, thereby preventing a cleaner from activating the non-contacting switch by false triggering during the cleaning operation.

A non-contacting switch control system provided by the present disclosure includes: a switch set, configured to receive a sensing signal from a sensing target, the switch set including a first non-contacting switch and a second non-contacting switch; a storage unit, configured to store a control program; and a processing unit, connected to the switch set and the storage unit, and configured to execute the control program and control the switch set based on the sensing signal. The control program includes: in a first operating mode, determining whether the first non-contacting switch receives an identification signal, and obtaining a first determination result; and when the first determination result is true, configuring the non-contacting switch control system to enter a second operating mode and disabling the second non-contacting switch.

According to one embodiment of the present disclosure, the above-mentioned non-contacting switch control system further includes: a timing unit, connected to the processing unit and configured to count in a first time period; and the control program further includes: when the non-contacting switch control system enters the second operating mode, counting the first time period by the timing unit; and when counting for the first time period is completed, configuring the non-contacting switch control system to enter the first operating mode.

According to one embodiment of the present disclosure, in the above-mentioned non-contacting switch control system, the switch set includes: a receiving unit, configured to receive the identification signal, the identification signal including: an external signal sent by an external device.

According to one embodiment of the present disclosure, in the above-mentioned non-contacting switch control system, the switch set includes: an emitting unit and a receiving unit; the identification signal includes: a reflection signal of an internal signal; and the emitting unit emits the internal signal to the sensing target, and the receiving unit receives the reflection signal of the internal signal.

According to one embodiment of the present disclosure, in the above-mentioned non-contacting switch control system, the timing unit is further configured to count in a second time period, and the control program further includes: when the first non-contacting switch receives the identification signal, counting the second time period by the timing unit, determining whether the first non-contacting switch receives the identification signal continuously in the second time period, and obtaining a second determination result; and when the second determination result is true, configuring the non-contacting switch control system to enter the second operating mode and disabling the second non-contacting switch.

According to one embodiment of the present disclosure, the above-mentioned non-contacting switch control system further includes: a timing unit, connected to the processing unit and configured to count a sensing count; the timing unit is further configured to count in a second time period, and the control program further includes: when the first non-contacting switch receives the identification signal, counting the second time period by the timing unit, determining whether the sensing count is greater than or equal to a sensing count threshold in the second time period, and obtaining a third determination result; and when the third determination result is true, configuring the non-contacting switch control system to enter the second operating mode and disabling the second non-contacting switch.

According to one embodiment of the present disclosure, the above-mentioned non-contacting switch control system further includes: a prompt unit, connected to the processing unit and configured to provide an operating mode prompt.

In conclusion, the non-contacting switch control system of the present disclosure may take one or more non-contacting switches of the plurality of non-contacting switches as the first non-contacting switch, and take one or more non-contacting switches as the second non-contacting switch. When the first non-contacting switch receives the identification signal in the first operating mode (i.e., the standby mode), the non-contacting switch control system may enter the second operating mode (i.e., the cleaning mode or the disabling mode), and the processing unit may disable the second non-contacting switch in the second operating mode by, for example, sending a disabling instruction, so that a switch function of the non-contacting switch designated as the second non-contacting switch in the plurality of non-contacting switches is disabled, thereby preventing the cleaner from activating the non-contacting switch by false triggering during the cleaning operation. With the above structure of the present disclosure, the non-contacting switches may not be activated by false triggering of the cleaner during the cleaning operation. For example, the present disclosure may also be applied to an elevator system, and the cleaner is prevented from false triggering the non-contacting switches of the present disclosure during the cleaning operation. Therefore, when the present disclosure is applied to, for example, the elevator system, the present disclosure further has the technical effects of saving power and saving the waiting time of users by reducing unnecessary elevator calls.

Other objectives, features and advantages of the invention will be further understood from the further technological features disclosed by the embodiments of the invention wherein there are shown and described preferred embodiments of this invention, simply by way of illustration of modes best suited to carry out the invention.

### BRIEF DESCRIPTION OF THE DRAWINGS

FIG. 1 is a block diagram illustrating a non-contacting switch control system according to an embodiment of the present disclosure.

FIG. 2 is a block diagram illustrating a non-contacting switch according to an embodiment of the present disclosure.

FIG. 3 is a schematic diagram illustrating a floating display touch switch according to an embodiment of the present disclosure.

FIG. 4 is a flowchart according to an embodiment of the present disclosure.

FIG. 5 is a block diagram illustrating a non-contacting switch control system according to another embodiment of the present disclosure.

FIG. 6 is a flowchart according to another embodiment of the present disclosure.

FIG. 7 is a block diagram illustrating a non-contacting switch control system according to yet another embodiment of the present disclosure.

### DETAILED DESCRIPTION OF PREFERRED EMBODIMENTS

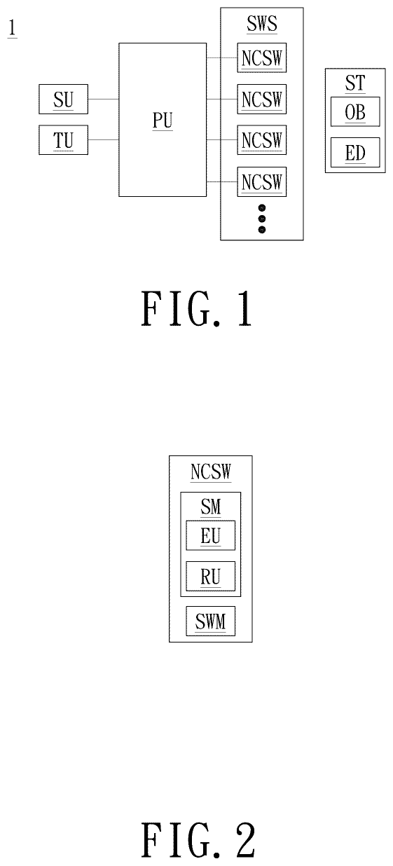

Reference is made to FIG. 1 and FIG. 2. FIG. 1 is a block diagram illustrating a non-contacting switch control system according to an embodiment of the present disclosure, and FIG. 2 is a block diagram illustrating a non-contacting switch according to an embodiment of the present disclosure.

According to this embodiment, the non-contacting switch control system 1 of the present disclosure includes: a switch set SWS, a processing unit PU, a storage unit SU, and a timing unit TU. The switch set SWS includes a plurality of non-contacting switches NCSW. The processing unit PU is connected to the plurality of non-contacting switches NCSW, the storage unit SU, and the timing unit TU.

According to this embodiment, operating modes of the non-contacting switch control system 1 of the present disclosure may include a first operating mode (i.e., a standby mode) and a second operating mode (i.e., a cleaning mode, which can be considered as a disabling mode). Moreover, the non-contacting switch control system 1 may change/determine a switch state of each non-contacting switch NCSW according to the non-contacting switches NCSW receiving a sensing signal from a sensing target ST in a sensing region, and transmit the sensing signal to the processing unit PU. Then, a control program stored in the storage unit SU will be executed by the processing unit PU. The sensing target ST may be an external device ED or a non-specific object OB (e.g., the sensing target ST may be a wireless signal emitting device, a remote control, a human body, a part of the human body, and other devices or objects with a function of transmitting sensing signals; and the sensing signal of the sensing target ST may be a wireless signal transmitted via a communication protocol, a human body capacitance value, an infrared light/ultrasonic reflection signal, etc.). The processing unit PU may define at least one non-contacting switch NCSW of the plurality of non-contacting switches NCSW as a first non-contacting switch (or a trigger switch), and define one or more non-contacting switches as second non-contacting switches (i.e., a non-contacting switch NCSW designated to be disabled in the system). When the first non-contacting switch receives an identification signal in the first operating mode (i.e., the standby mode), the non-contacting switch control system may enter the second operating mode (i.e., the cleaning mode or the disabling mode), and the processing unit may disable the second non-contacting switch in the second operating mode by, for example, sending a disabling instruction, so that a switch function of the non-contacting switch designated as the second non-contacting switch in the plurality of non-contacting switches is disabled.

In order to avoid ambiguous definitions of terms, some of the terms used in the embodiments of the present disclosure are first explained below.

According to the present disclosure, the first non-contacting switch refers to a non-contacting switch NCSW used for triggering the second operating mode (i.e., the cleaning mode or the disabling mode). In the non-contacting switch control system 1, the first non-contacting switch may be a non-contacting switch NCSW designated/preset as a trigger switch, that is, the first non-contacting switch is one or more non-contacting switches NCSW selected from the plurality of non-contacting switches NCSW in the switch set SWS, and each non-contacting switch NCSW in the switch set SWS may be designated/preset as the first non-contacting switch.

According to the present disclosure, the second non-contacting switch refers to a non-contacting switch NCSW disabled in the second operating mode (i.e., the cleaning mode or the disabling mode), that is, the second non-contacting switch is selected from the plurality of non-contacting switches NCSW in the switch set SWS, there may be one or more second non-contacting switches, and each non-contacting switch NCSW in the switch set SWS may be designated/preset as the second non-contacting switch. According to one of the embodiments, each non-contacting switch NCSW in the switch set SWS may be designated/preset as the first non-contacting switch and the second non-contacting switch at the same time.

According to the present disclosure, the term “disable” refers to an action of arranging a component to lose an original function in the system. For example, disabling the second non-contacting switch may refer to an action of configuring the processing unit PU to ignore a signal from the second non-contacting switch, or an action that the processing unit PU sends a control signal to configure the second non-contacting switch to temporarily ignore an instruction to the second non-contacting switch. According to one of the embodiments, the processing unit PU may send a stop instruction to configure an emitting unit EU of the second non-contacting switch to stop emitting a wireless signal and thus prevent the second non-contacting switch from receiving a reflection signal (i.e., the sensing signal of the sensing target ST) of the wireless signal, thereby achieving the technical effect of disabling the second non-contacting switch to avoid false triggering. Disabling refers to the action of configuring the component to lose the original function in the system (e.g., a switch loses a trigger function), and the implementation is not limited by the present disclosure here.

According to the present disclosure, the identification signal refers to a signal used for triggering the second operating mode (i.e., the cleaning mode or the disabling mode). For example, the identification signal may be an external signal (or a wireless signal) sent by the external device ED, or a reflection signal reflected by the sensing target ST after the emitting unit EU of the first non-contacting switch emits an internal signal to the sensing target ST, that is, the identification signal may also be a reflection signal of the internal signal. The identification signal may include: the external signal sent by the external device ED, or the reflection signal of the internal signal.

Next, a sensing module SM of the non-contacting switch NCSW will be described below.

According to one embodiment of the present disclosure, the non-contacting switch NCSW may include: the sensing module SM and a switch module SWM. The sensing module SM may further include: an emitting unit EU and a receiving unit RU.

For example, the sensing module SM may be a capacitive sensing module. When the sensing module SM is a capacitive sensing module, the sensing target ST may be a human body, a part of the human body, or any object OB that may change a capacitance value sensed by the sensing module SM. The capacitive sensing module may sense the capacitance value of the human body, and the processing unit PU may transmit a first control signal to control the switch module SWM based on the change of the capacitance value.

For example, the sensing module SM may be an infrared light sensing module, and the sensing module SM may include the emitting unit EU and the receiving unit RU. When the sensing module SM is an infrared light sensing module, the sensing target ST may be a human body, a part of the human body, or an object OB that may reflect infrared light (i.e., the reflection signal of the internal signal) emitted by the emitting unit EU used for emitting the infrared light. The receiving unit RU of the sensing module SM may receive the infrared light obtained by reflecting the infrared light emitted by the emitting unit EU by the object OB. The processing unit PU may transmit a control signal to control the switch module SWM based on the sensing signal (i.e., the reflection signal of the internal signal) of the sensing target received by the receiving unit RU. According to one of the embodiments, the receiving unit RU of the sensing module SM may receive the sensing signal from the sensing target ST, the sensing signal including: the external signal sent by the external device ED. The external device ED includes a transmission unit for transmitting an infrared light wireless signal.

For example, the sensing module SM may be an ultrasonic sensing module, and the sensing module SM may include the emitting unit EU and the receiving unit RU. When the sensing module SM is an ultrasonic sensing module, the sensing target ST may be a human body, a part of the human body, or an object OB that may reflect an ultrasonic wireless signal (i.e., the reflection signal of the internal signal) emitted by the emitting unit EU for emitting the ultrasonic wireless signal. The receiving unit RU of the sensing module SM may receive the ultrasonic wireless signal obtained by reflecting the ultrasonic wireless signal emitted by the emitting unit EU by the object OB. The processing unit PU may transmit a control signal to control the switch module SWM based on the sensing signal (i.e., the reflection signal of the internal signal) of the sensing target received by the receiving unit RU. According to one of the embodiments, the receiving unit RU of the sensing module SM may receive the sensing signal from the sensing target ST, the sensing signal including: the external signal sent by the external device ED. The external device ED includes a transmission unit for transmitting the ultrasonic wireless signal.

According to one of the embodiments, the internal signal and the external signal may use the same communication protocol, and the processing unit PU may identify the internal signal and the external signal by transmitting data of different values. Taking 16-digit data as an example, when the transmitted internal signal is 0x55, the external signal may be defined as 0x99, so that the internal signal is distinguished from the external signal to control a switch state of the switch module SWM, or to trigger the non-contacting switch control system 1 to enter the second operating mode.

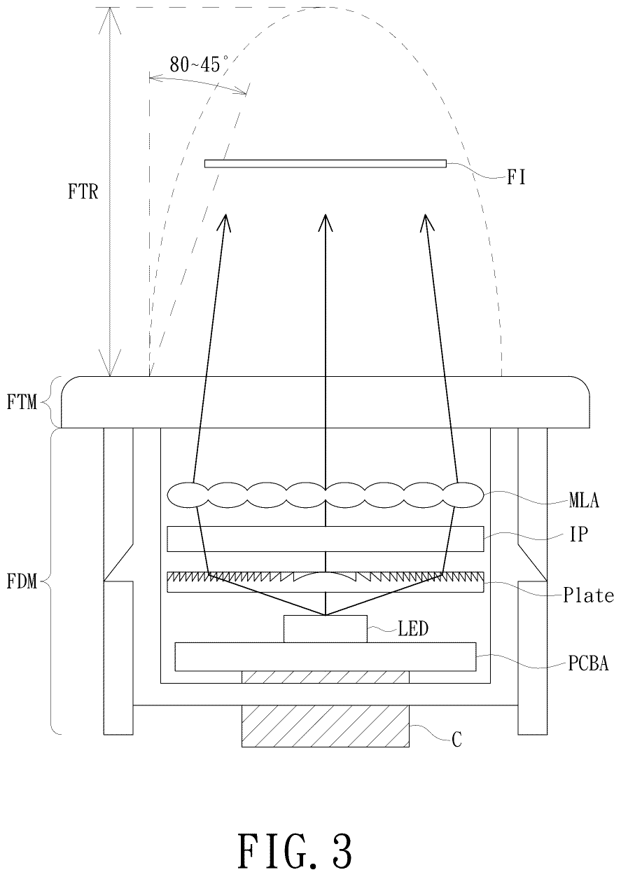

Next, reference is made to FIG. 3. According to one of the embodiments, the non-contacting switch NCSW is implemented as a floating display touch switch, and FIG. 3 is a schematic diagram illustrating a floating display touch switch according to an embodiment of the present disclosure. The floating display touch switch includes: a floating display module FDM and a floating touch module FTM. The floating display module FDM includes: a microlens array MLA, an imaging plate IP, a plate lens Plate, a circuit board PCBA, a light-emitting diode LED, and a connector C. The floating display touch switch according to this embodiment may receive the sensing signal from the sensing target ST in the sensing region FTR by the floating touch module FTM (the floating touch module FTM includes: the sensing module SM). The sensing region may include a sensing distance and a sensing angle. The sensing distance may be a distance from a sensing surface of the sensing module SM to the sensing target ST, for example, 0 to 10 cm. The sensing angle may be an angle formed by inward retraction from any point on the outer edge (e.g., 0 cm) of the sensing surface of the sensing module SM to a sensing failure point (i.e., a distance that does not react to the sensing target ST, e.g., 10 cm), for example, 80 degrees to 45 degrees.

The above examples are provided only as exemplary embodiments of the non-contacting switch NCSW of the present disclosure, and the present disclosure is not limited to the exemplified embodiments. Any device that can provide a sensing region, receive a sensing signal from a sensing target in the sensing region, and control a switch state of a switch module SWM via a processing unit PU may be used as the non-contacting switch NCSW of the present disclosure.

Next, the switch module SWM of the non-contacting switch NCSW will be described below.

According to this embodiment, the switch module SWM of the non-contacting switch NCSW of the present disclosure refers to a device used as a switch in a circuit. The switch module SWM has a switch state. The switch state refers to a switch state of the switch module SWM in the circuit. The switch state may include an open-circuit state and a short-circuit state. The processing unit PU may switch the switch state of the switch module SWM by, for example, transmitting a control signal. The switch module SWM may be connected to other external circuits so that the processing unit PU may control the external circuits based on the switch state of the switch module SWM. For example, the switch module SWM may be a multistage diverter switch (which can yield an open/short circuit), or a transistor switch (which can control a transistor to act in a cutoff/saturation region by controlling a voltage/current, where the switch state may be regarded as the open-circuit state of the present disclosure when the transistor acts in the cutoff region, and the switch state may be regarded as the short-circuit state of the present disclosure when the transistor acts in the saturation region), or a logic circuit. However, the present disclosure is not limited thereto, and any device that may control an external circuit by changing the switch state may be used as the switch module SWM of the present disclosure.

The non-contacting switch control system 1 of the present disclosure includes the timing unit TU. The timing unit TU refers to a device connected to the processing unit PU and configured to calculate a time period. For example, the timing unit TU may be a timing device that is repeatedly opened and closed through a motor, a coil or other components and calculates a time unit (e.g., seconds, minutes, and hours) based on the number of times of open/short circuits of counting contacts of the timing unit TU. However, the present disclosure is not limited thereto, and any timing device that may calculate time may be used as the timing unit TU of the present disclosure.

The non-contacting switch control system 1 of the present disclosure includes the storage unit SU. The storage unit SU refers to a device connected to the processing unit PU and configured to store the control program. The control program may include: in the first operating mode, determining whether the first non-contacting switch receives the identification signal, and obtain a first determination result; when the first determination result is true, configuring the non-contacting switch control system to enter the second operating mode and disable the second non-contacting switch; when the non-contacting switch control system enters the second operating mode, counting a first time period by the timing unit; when counting in the first time period is completed, configuring the non-contacting switch control system to enter the first operating mode; when the first non-contacting switch receives the identification signal, counting a second time period by the timing unit, determining whether the first non-contacting switch receives the identification signal continuously in the second time period, and obtaining a second determination result; when the second determination result is true, configuring the non-contacting switch control system to enter the second operating mode and disabling the second non-contacting switch; when the first non-contacting switch receives the identification signal, counting in the second time period by the timing unit, determining whether a sensing count is greater than or equal to a sensing count threshold in the second time period, and obtaining a third determination result; and when the third determination result is true, configuring the non-contacting switch control system to enter the second operating mode and disabling the second non-contacting switch. The processing unit PU may be further configured to execute the control program. For example, the storage unit SU may be a non-volatile memory, a memory card, a buffer, or other devices with the same function. The enumerated types of storage devices are merely examples and are not intended to limit the present disclosure, and all storage devices with the same function may be used as the storage unit SU of the present disclosure.

The non-contacting switch control system 1 of the present disclosure includes the processing unit PU. The processing unit PU refers to a device that is connected to the switch set SWS, the storage unit SU and the timing unit TU as a processing core of the device, and configured to execute the control program stored in the storage unit SU to control the switch state of the switch module SWM. For example, the processing unit PU may be a microcontroller unit (MCU), a central processing unit (CPU), or other devices with the same function. The enumerated types of processing units are merely examples and are not intended to limit the present disclosure, and any device that may execute the control program stored in the storage unit SU to control the switch state of the switch module SWM may be used as the processing unit PU of the present disclosure.

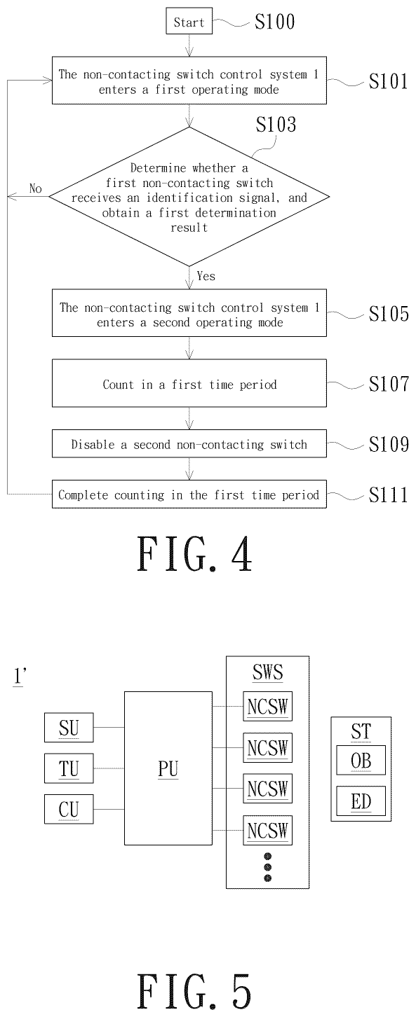

Next, reference is made to FIG. 4. FIG. 4 is a flowchart according to an embodiment of the present disclosure.

According to this embodiment, the processing unit PU may execute the control program to configure the non-contacting switch control system 1 to perform the following flow: Step S100: The flow starts, and then the flow enters Step S101. Step S101: Configure the non-contacting switch control system 1 to enter the first operating mode (i.e., enter the standby mode), and then the flow enters Step S103. Step S103: Determine whether the first non-contacting switch receives the identification signal, and obtain the first determination result (could be true or false, i.e., “Yes” or “No”), if the first determination result is false, the flow returns to Step S101 (i.e., return to the standby mode, thereby polling to determine whether the first non-contacting switch receives the identification signal), and if the first determination result is true, enters Step S105. Step S105: When the first determination result is true, configure the non-contacting switch control system 1 to enter the second operating mode (i.e., the cleaning mode and the disabling mode), and then the flow enters Step S107. Step S107: Start, by the timing unit, to count in the first time period, and then the flow enters Step S109. Step S109: Disable the second non-contacting switch, and the flow enters Step S111. Step S111: When counting in the first time period is completed, configure the non-contacting switch control system to enter the first operating mode (i.e., the non-contacting switch control system 1 enters the second operating mode to count in a preset period of time, and returns to the standby mode when the preset period of time is up).

Next, reference is made to FIG. 5. FIG. 5 is a block diagram illustrating a non-contacting switch control system 1′ according to another embodiment of the present disclosure.

The present disclosure provides various implementations. According to the various embodiments of the present disclosure, components/devices with the same reference numeral indicate that the functions of the components/devices may also include the same functions as other embodiments, which are thus not repeated in the various embodiments of the present disclosure, and only the differences from other embodiments will be described. The items and steps mentioned in the various embodiments may be rearranged and combined without any conflict, and are applied to the various embodiments. The present disclosure is not limited to the exemplified embodiments.

According to this embodiment, the non-contacting switch control system 1′ of the present disclosure includes: a switch set SWS, a processing unit PU, a storage unit SU, a timing unit TU, and a timing unit CU. The switch set SWS includes a plurality of non-contacting switches NCSW. The processing unit PU is connected to the plurality of non-contacting switches NCSW, the storage unit SU, the timing unit TU, and the timing unit CU.

According to this embodiment, the non-contacting switch control system 1′ of the present disclosure further includes the timing unit CU. The timing unit CU refers to a device connected to the processing unit PU and configured to count a sensing count of identification signals. The present disclosure may also count the sensing count of the identification signals through the timing unit CU. For example, according to this embodiment, a user may trigger a first non-contacting switch repeatedly with hands, and the non-contacting switch control system 1′ may enter a second operating mode when the sensing count of the timing unit CU is greater than or equal to a sensing count threshold.

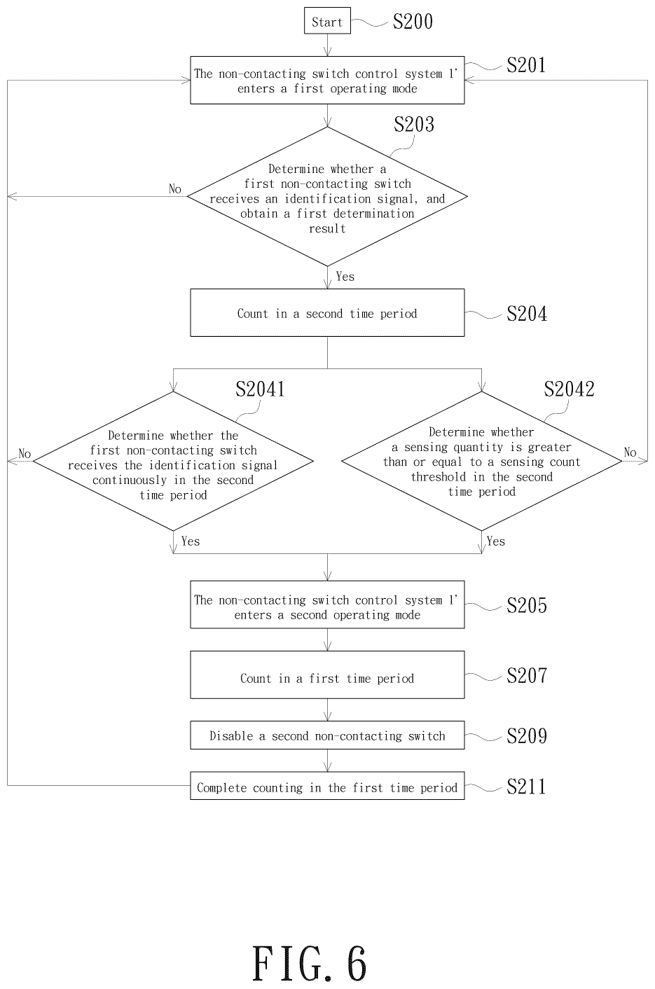

Next, reference is made to FIG. 6. FIG. 6 is a flowchart according to another embodiment of the present disclosure.

According to this embodiment, the processing unit PU may execute a control program to configure the non-contacting switch control system 1′ to perform the following flow: Step S200: The flow starts, and then the flow enters Step S201. Step S201: Configure the non-contacting switch control system 1′ to enter a first operating mode (i.e., enter a standby mode), and then the flow enters Step S203. Step S203: Determine whether the first non-contacting switch receives an identification signal, and obtain a first determination result (true of false, i.e., “Yes” or “No”); if the first determination result is false, the flow returns to Step S201 (i.e., returning to the standby mode, thereby polling to determine whether the first non-contacting switch receives the identification signal), and if the first determination result is true, the flow enters Step S204. Step S204: Count in a second time period, and then the flow enters Step S2041 or S2042 (the flow may merely include one of Step S2041 and Step S2042, or may include Step S2041 and Step S2042 at the same time based on user requirements). Step S2041: Determine whether the first non-contacting switch receives the identification signal continuously in the second time period (e.g., the hand is put in a sensing region of a sensing module SM), to obtain a second determination result; if the second determination result is false (i.e., “No”), the flow enters Step S201; and if the second determination result is true, the flow enters Step S205. Step S2042: Determine whether the sensing count is greater than or equal to the sensing count threshold in the second time period, to obtain a third determination result; if the third determination result is false, the flow enters Step S201; and if the third determination result is true, the flow enters Step S205. Step S205: Configure the non-contacting switch control system 1′ to enter the second operating mode (i.e., a cleaning mode and a disabling mode), and then the flow enters Step S207. Step S207: The timing unit counts in a first time period, and then the flow enters Step S209. Step S209: Disable a second non-contacting switch, and then the flow enters Step S211. Step S211: When counting for the first time period is completed, configure the non-contacting switch control system 1′ to enter the first operating mode.

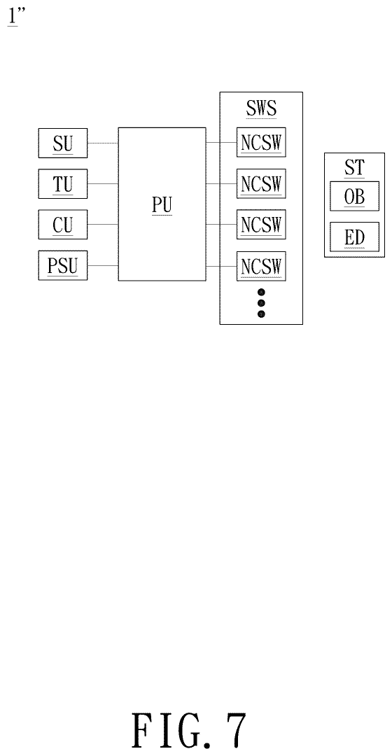

Next, reference is made to FIG. 7. FIG. 7 is a block diagram illustrating the non-contacting switch control system 1″ according to an embodiment of the present disclosure.

According to this embodiment, the non-contacting switch control system 1″ of the present disclosure further includes a prompt unit PSU. The prompt unit PSU is connected to the processing unit PU and configured to supply an operating mode prompt. The prompt unit PSU may be included in the non-contacting switch NCSW, or may be a standalone device. The prompt unit PSU may be a buzzer, a light-emitting diode, a liquid crystal display, etc. The prompt unit PSU may provide different prompt information when the system enters different operating modes, or provide prompt information only in a specific operating mode. For example, when a cleaner triggers the control switch to configure the system to enter the first operating mode, the prompt unit PSU may send prompt information (e.g., audio information, text information and color information) to prompt the cleaner that the system has entered the cleaning mode currently and the designated non-contacting switch NCSW is in a disabled state by making a sound, turning on light-emitting diodes of different colors, displaying text and other manners, and stop sending the prompt information after the first operating mode ends (i.e., entering the standby mode). According to one of the embodiments, the prompt unit PSU may also send different prompt information for different operating modes. For example, the non-contacting switch control system 1″ may include a plurality of light-emitting diodes of different colors, and turn on the light-emitting diodes of different colors in the first operating mode, the second operating mode, and the standby operating mode respectively. By prompting the cleaner through the light-emitting diodes of different colors, the cleaner may quickly know a current operating mode of the system, thereby achieving a technical effect of quickly determining the operating mode of the system.

In conclusion, the non-contacting switch control system of the present disclosure may take one or more non-contacting switches of the plurality of non-contacting switches as the first non-contacting switch, and take one or more non-contacting switches as the second non-contacting switch. When the first non-contacting switch receives the identification signal in the first operating mode (i.e., the standby mode), the non-contacting switch control system may enter the second operating mode (i.e., the cleaning mode or the disabling mode), and the processing unit may disable the second non-contacting switch in the second operating mode by, for example, sending a disabling instruction, so that a switch function of the non-contacting switch designated as the second non-contacting switch in the plurality of non-contacting switches is disabled, thereby preventing the cleaner from activating the non-contacting switch by false triggering during the cleaning operation. With the above structure of the present disclosure, the non-contacting switches may not be activated by false triggering of the cleaner during the cleaning operation. For example, the present disclosure may also be applied to an elevator system, and the cleaner is prevented from false triggering the non-contacting switches of the present disclosure during the cleaning operation. Therefore, when the present disclosure is applied to, for example, the elevator system, the present disclosure can further provide the technical effects of saving power and saving the waiting time of users by reducing unnecessary elevator summoning.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A non-contacting switch control system, comprising:
a switch set, configured to receive a sensing signal from a sensing target, the switch set comprising a first non-contacting switch and a second non-contacting switch;
a storage unit, configured to store a control program; and
a processing unit, connected to the switch set and the storage unit, and configured to execute the control program and control the switch set based on the sensing signal,
wherein the control program comprises:
in a first operating mode, determining whether the first non-contacting switch receives an identification signal and obtaining a first determination result; and
when the first determination result is true, configuring the non-contacting switch control system to enter a second operating mode and disabling the second non-contacting switch.

2. The non-contacting switch control system according to claim 1, further comprising:
a timing unit, connected to the processing unit, and configured to count in a first time period,
wherein the control program further comprises:
when the non-contacting switch control system enters the second operating mode, counting in the first time period by the timing unit; and
when counting the first time period is completed, configuring the non-contacting switch control system to enter the first operating mode.

3. The non-contacting switch control system according to claim 1, wherein the switch set comprises:
a receiving unit configured to receive the identification signal, the identification signal comprising an external signal sent by an external device.

4. The non-contacting switch control system according to claim 1, wherein the switch set comprises an emitting unit and a receiving unit, and the identification signal comprises a reflection signal of an internal signal; and the emitting unit emits the internal signal to the sensing target, and the receiving unit receives the reflection signal of the internal signal.

5. The non-contacting switch control system according to claim 2, wherein the timing unit is further configured to count in a second time period, and the control program further comprises:
when the first non-contacting switch receives the identification signal, counting in the second time period by the timing unit, determining whether the first non-contacting switch receives the identification signal continuously in the second time period, and obtaining a second determination result; and
when the second determination result is true, configuring the non-contacting switch control system to enter the second operating mode and disabling the second non-contacting switch.

6. The non-contacting switch control system according to claim 2, further comprising a timing unit connected to the processing unit and configured to count in a sensing count, wherein the timing unit is further configured to count in a second time period, and the control program further comprises:
when the first non-contacting switch receives the identification signal, counting in the second time period by the timing unit, determining whether the sensing count is greater than or equal to a sensing count threshold in the second time period, and obtaining a third determination result; and
when the third determination result is true, configuring the non-contacting switch control system to enter the second operating mode and disabling the second non-contacting switch.

7. The non-contacting switch control system according to claim 1, further comprising:
a prompt unit, connected to the processing unit and configured to provide an operating mode prompt.
